(19) United States
(12) Patent Application Publication
(10) Pub. No.: US 2008/0164481 A1
(43) Pub. Date: Jul. 10, 2008

(54) Image display apparatus with ambient light sensing system

(75) Inventors: Mitsuharu Tai, Kokubunji (JP); Hiroshi Kageyama, Hachioji (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 11/987,852

(22) Filed: Dec. 5, 2007

(30) Foreign Application Priority Data
Jan. 9, 2007 (JP) 2007-001117

(51) Int. Cl. H01L 33/00

(52) U.S. Cl. 257/81; 257/E33.076

(57) ABSTRACT

An image display apparatus with an illuminance sensor, where the packaging cost, mechanical reliability due to packaging, and product yield are maintained. In the same semiconductor film as a thin-film-transistor (TFT) consisting of a pixel formed over an insulating substrate constituting a pixel, plural photo-sensors composed of a TFT for detecting light which has different detecting wavelength bands, and a signal processing circuit for generating a signal which controls the brightness of the pixel on the basis of the output of the photo-sensor are formed. The photo-sensor detects light energy of different wavelength bands by using a filter having a different film thickness of the semiconductor film or a different light transmission band. Ambient illuminance is detected by processing the output of each sensor in the signal processing circuit. The detected signal is fed back to the brightness control of the pixel.

### CLAIM OF PRIORITY

The present application claims priority from Japanese application JP 2007-001117 filed on Jan. 9, 2007, the content of which is hereby incorporated by reference into this application.

### FIELD OF THE INVENTION

The present invention relates to an image display apparatus which has an ambient light sensing system where the brightness of a display image is controlled corresponding to the illuminance of the surroundings by using a photo-sensor generating a control signal corresponding to the illuminance of the surroundings.

### BACKGROUND OF THE INVENTION

A so-called display with an ambient light sensing system is known, where the brightness of a display image of an image display apparatus (hereinafter, it is also called a display) is controlled corresponding to the ambient light of the surroundings. A basic configuration of this kind of display generally has one detecting element (photo-sensor) for detecting ambient light (light around the display), a signal processing circuit for processing the output signal of the photo-sensor, and a backlight in a liquid crystal display apparatus or a feedback circuit or a device for giving a brightness control signal to the light emission element in a self-luminescence type image display apparatus such as an organic EL display, etc.

Each of the aforementioned circuits and devices are packed over a display panel part (hereinafter, it is simply called a panel) constituting a display or a suitable part of a component of the display in the shape of a semiconductor chip. In this case, the packaging cost, mechanical reliability due to packaging, and product yield have to be maintained.

Then, in these days, as described in Sharp Technical Journal, No. 24, vol. 92, pp. 35-39 (a system-in liquid crystal display where an ambient light sensor system is built-in using poly-Si), there have been attempts where a light sensor, a signal processing circuit, and a feedback circuit are built into the panel of the display in a semiconductor manufacturing process which is the same as that for a display.

It is assumed that plural sensor elements for detecting independent wavelength bands and a circuit for arithmetic processing the output thereof are included and they are industrially utilized; JP-A No. 10(1994)-122961 describes a sensor apparatus including plural sensor elements and discloses a micro spectrometer where each photo-sensor detects a specific wavelength by using an optical filter and spectral analysis is performed. Moreover, JP-A No. 2002-522763 discloses plural photodiodes (sensor) having different detecting wavelength bands and a fiber-color classification system which has a processing means for judging the classification of a fiber.

FIGS. 10A to 10C explain a liquid crystal panel as a configuration example of a conventional panel of a display with an ambient light sensing system. FIG. 10A is a rear elevation (rear face plane view) of a panel, FIG. 10B is a bottom view of a panel (lower side view), and FIG. 10C is a front view (display face plane view) of a panel. A liquid crystal is enclosed in the gap adhered between a first substrate (active substrate, thin-film-transistor substrate, and TFT substrate) SUB 1 and the second substrate (counter substrate and color filter substrate) SUB2.

Over the main face (inside face) of the first substrate SUB 1, pixel circuits consisting of thin film transistors (TFT) are formed arrayed in a matrix state to form a pixel region (display region). Over the main face the second substrate SUB 2, plural color filters and counter electrodes are formed in a twisted nematic method (TN method) system and a color pixel is formed together with the pixel electrode constituting a pixel circuit of the first substrate SUB 1. In an in-plane-switching method (IPS method) system a counter electrode is formed over the main face of the first substrate SUB1. Moreover, there may be one where a color filter is formed at the side of the first substrate SUB1. Peripheral circuits, etc. such as a driver which selects a pixel and supplies a display signal are packaged on the periphery of the pixel region of the first substrate SUB 1 in the shape of a semiconductor chip.

A backlight is installed at the backside of the first substrate SUB 1 but it has been omitted in the figure. Then, a printed circuit board PCB is attached to the backside thereof, where a display control circuit chip DLS, etc. is mounted. In one where a driver, etc. is packaged in the shape of a semiconductor chip, the substrate size of the second substrate SUB2 is a little smaller than that of the first substrate SUB2 and a driver DR is formed on the periphery of the first substrate SUB 1 which lies away from the edge of the second substrate SUB 2. In one where the driver DR is formed over the substrate in a formation process of plural pixels constituting the pixel region AR, there is a case where the part for forming the driver DR is also covered with the second substrate SUB 2. Other control circuits, etc. are packaged in the shape of a semiconductor chip (LSI) over the printed circuit board PCB.

The gap between the driver DR and the printed circuit board PCB is connected by a flexible printed circuit board FPCB. Over the first substrate SUB 1 lying away from the second substrate SUB 2, a sensor (photo-sensor chip) PSE is packaged at a different part of the driver DR formation part and the gap with the printed circuit board PCB on which the signal processing circuit for the sensor is mounted is connected by the flexible printed circuit board FPCA.

### SUMMARY OF THE INVENTION

A silicon (Si) semiconductor or a compound semiconductor used for a photo-sensor has a specific absorption coefficient (permeability) and a wavelength dependence (for instance, refer to the following FIG. 3). In this case, the most appropriate film thickness of a semiconductor will differ in light of each wavelength band. Therefore, when one kind of sensor is built-in, there is a wavelength band having absorption properties which differ from a desired one and a relationship develops between the illuminance and the sensor output. As a result, highly accurate detection and control cannot be obtained (for instance, a wavelength band following the visual sensitivity and the absorption intensity distribution cannot be replicated by using one kind of sensor).

Moreover, as disclosed in JP-A No. 10(1994)-122961 and JP-A No. 2002-522763, desired light can be detected by constructing a sensor-control structure including plural sensors where each sensor detects an individual wavelength band and a circuit which processes the output thereof. However, it is not one which solves a realistic problem where the difficulty of packaging into an image display apparatus is solved.

It is an objective of the present invention to provide an image display apparatus with illuminance sensor for maintaining packaging cost, mechanical reliability caused by packaging, and product yield.

In order to achieve the aforementioned objective, over an insulating substrate constituting a pixel circuit and in the same semiconductor film as a thin film transistor (TFT) comprising the pixel circuit, the present invention includes plural light sensors composed of a TFT for detecting light which has different detecting wavelength bands and a signal processing circuit for generating a signal which controls the brightness of the pixel on the basis of the output of the photo-sensor. The photo-sensor detects light energy of different wavelength bands by using a filter having a different film thickness of the semiconductor or a different light transmission band. Ambient illuminance is detected by processing the output of each sensor in the signal processing circuit. A configuration was assumed in which the detected signal is fed back to the brightness control of the pixel.

In the process for forming the pixel region of the image display apparatus (and driver part), a signal processing circuit for generating a control signal corresponding to the photo-sensor and the illuminance, and the packaging cost, mechanical reliability caused by packaging, and product yield can be maintained.

### BRIEF DESCRIPTION OF THE DRAWINGS

FIG. 1 is a drawing illustrating a liquid crystal panel as a structural example of an ambient light sensing system built-in type display panel of the present invention;

FIG. 2 is a drawing illustrating a wavelength dependence of spectral luminous efficiency;

FIG. 3 is a figure for explaining the sensitivity properties of photo-sensors made of silicon materials;

FIG. 4A are figures for showing energy spectra at the output part of a photo-sensor in the first embodiment of the present invention;

FIG. 4B are figures for showing energy spectra of the output part of three different photo-sensors having different detecting regions in the first embodiment of the present invention;

FIG. 4C is a figure illustrating an example of a signal calculation of the output part of the photo-sensor in the first embodiment of the present invention;

FIG. 5 is a block diagram illustrating an example of a circuit for controlling the luminance (brightness) of a light source of a backlight for a liquid crystal;

FIG. 6A is a cross-sectional drawing illustrating an example of a manufacturing method of a liquid crystal panel with an ambient light sensing system, which is a process for configuring a photo-sensor using polysilicon;

FIG. 6B is a cross-sectional drawing following FIG. 6A illustrating an example of a manufacturing method of a liquid crystal panel with an ambient light sensing system, which is a process for configuring a photo-sensor using polysilicon;

FIG. 6C is a cross-sectional drawing following FIG. 6B illustrating an example of a manufacturing method of a liquid crystal panel with an ambient light sensing system, which is a process for configuring a photo-sensor using polysilicon;

FIG. 6D is a cross-sectional drawing following FIG. 6C illustrating an example of a manufacturing method of a liquid crystal panel with an ambient light sensing system, which is a process for configuring a photo-sensor using polysilicon;

FIG. 6E is a cross-sectional drawing following FIG. 6D illustrating an example of a manufacturing method of a liquid crystal panel with an ambient light sensing system, which is a process for configuring a photo-sensor using polysilicon;

FIG. 7A is a cross-sectional drawing illustrating an example of a manufacturing method of a liquid crystal panel with an ambient light sensing system, which is a process for configuring a photo-sensor using amorphous silicon;

FIG. 7B is a cross-sectional drawing following FIG. 7A illustrating an example of a manufacturing method of a liquid crystal panel with an ambient light sensing system, which is a process for configuring a photo-sensor using amorphous silicon;

FIG. 7C is a cross-sectional drawing following FIG. 7B illustrating an example of a manufacturing method of a liquid crystal panel with an ambient light sensing system, which is a process for configuring a photo-sensor using amorphous silicon;

FIG. 7D is a cross-sectional drawing following FIG. 7C illustrating an example of a manufacturing method of a liquid crystal panel with an ambient light sensing system, which is a process for configuring a photo-sensor using amorphous silicon;

FIG. 7E is a cross-sectional drawing following FIG. 7D illustrating an example of a manufacturing method of a liquid crystal panel with an ambient light sensing system, which is a process for configuring a photo-sensor using amorphous silicon;

FIG. 7F is a cross-sectional drawing following FIG. 7E illustrating an example of a manufacturing method of a liquid crystal panel with an ambient light sensing system, which is a process for configuring a photo-sensor using amorphous silicon.

FIG. 7G is a cross-sectional drawing following FIG. 7F illustrating an example of a manufacturing method of a liquid crystal panel with an ambient light sensing system, which is a process for configuring a light sensor using amorphous silicon;

FIG. 7H is a cross-sectional drawing following FIG. 7G illustrating an example of a manufacturing method of a liquid crystal panel with an ambient light sensing system, which is a process for configuring a photo-sensor using amorphous silicon;

FIG. 8A is a cross-sectional drawing illustrating an example of a manufacturing method of a liquid crystal panel with an ambient light sensing system, which is a process for configuring a photo-sensor using another polysilicon;

FIG. 8B is a cross-sectional drawing following FIG. 8A illustrating an example of a manufacturing method of a liquid crystal panel with an ambient light sensing system, which is a process for configuring a photo-sensor using another polysilicon;

FIG. 8C is a cross-sectional drawing following FIG. 8B illustrating an example of a manufacturing method of a liquid crystal panel with an ambient light sensing system, which is a process for configuring a photo-sensor using another polysilicon;

FIG. 8D is a cross-sectional drawing following FIG. 8C illustrating an example of a manufacturing method of a liquid crystal panel with an ambient light sensing system, which is a process for configuring a photo-sensor using another polysilicon.

FIG. 8E is a cross-sectional drawing following FIG. 8D illustrating an example of a manufacturing method of a liquid crystal panel with an ambient light sensing system, which is a process for configuring a photo-sensor using another polysilicon;

FIG. 8F is a cross-sectional drawing following FIG. 8E illustrating an example of a manufacturing method of a liquid crystal panel with an ambient light sensing system, which is a process for configuring a photo-sensor using another polysilicon;

FIG. 8G is a cross-sectional drawing following FIG. 8F illustrating an example of a manufacturing method of a liquid crystal panel with an ambient light sensing system, which is a process for configuring a photo-sensor using another polysilicon;

FIG. 9A is a plane view illustrating a sensor arrangement, etc. in an illuminance detector built-in region in a panel of a liquid crystal display apparatus as an embodiment of an image display apparatus of the present invention;

FIG. 9B is a cross-sectional drawing illustrating along the line A-B of FIG. 9A;

FIG. 10A is a drawing for explaining a liquid crystal panel as a configuration example of a conventional display with an ambient light sensing system;

FIG. 10B is a drawing for explaining a liquid crystal panel as a configuration example of a conventional display with an ambient light sensing system; and

FIG. 10C is a drawing for explaining a liquid crystal panel as a configuration example of a conventional display with an ambient light sensing system.

### DETAILED DESCRIPTION OF THE PREFERRED EMBODIMENTS

Hereinafter, the best embodiments of this invention will be described in detail referring to the accompanying drawings.

### First Embodiment

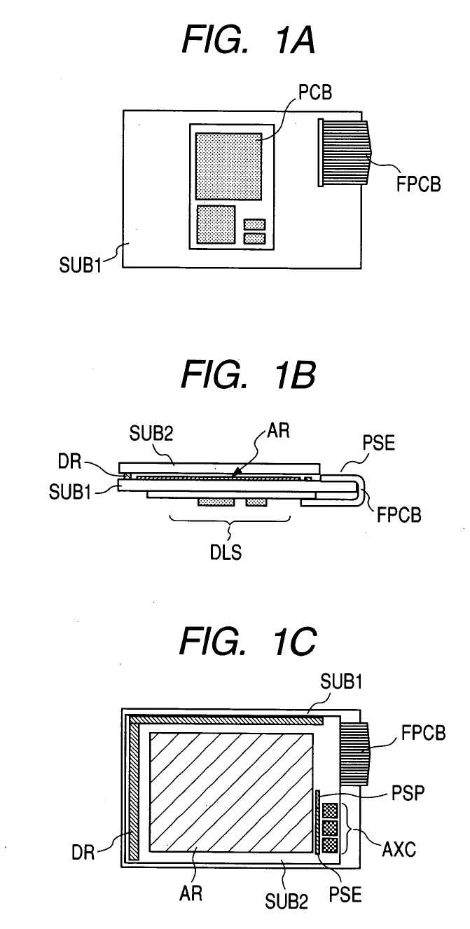

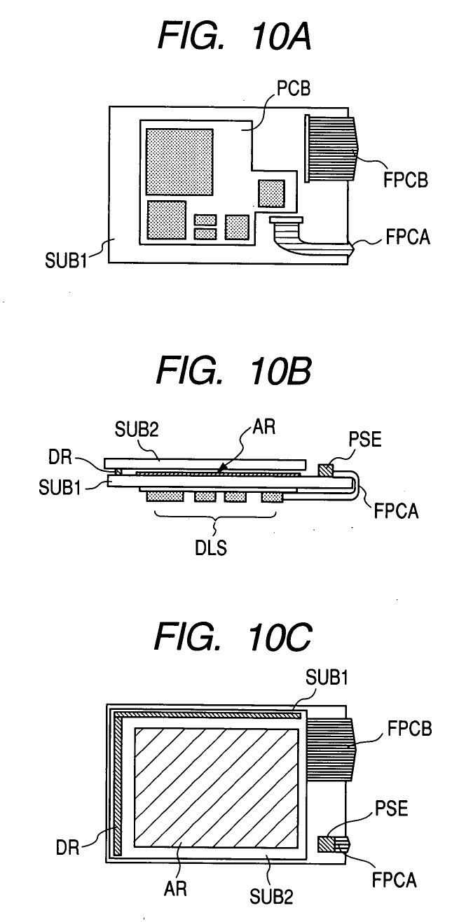

FIG. 1 is a drawing illustrating an example of a display panel of the present invention where an ambient light sensing system is built-in. FIG. 1A is a rear elevation of a panel, FIG. 1B is a bottom view of a panel, and FIG. 1C is a front view of a panel, the same as FIGS. 10A to 10C. The panel includes a first substrate SUB 1 and a second substrate SUB 2. Codes which are the same as FIGS. 10A to 10C correspond to parts having the same functions. Like FIGS. 10A to 10C, a backlight is not shown in the figure.

In the liquid crystal panel of the embodiment 1 where an ambient light sensing system is built-in, plural photo-sensors PSE, a signal processing circuit PSP, and a signal processing circuit AXC for generating a signal which controls the brightness of the pixel are formed simultaneously over the same substrate (first substrate SUB 1) in a pixel formation process. The output of the signal processing circuit PSP and the input of the control signal system, etc. are connected with a feedback circuit mounted over the printed circuit board PCB arranged at the backside of the first substrate SUB 1 using a flexible printed circuit board FPCB. The signal processing circuit AXC may be mounted in the shape of an LSI over the printed circuit board PCB.

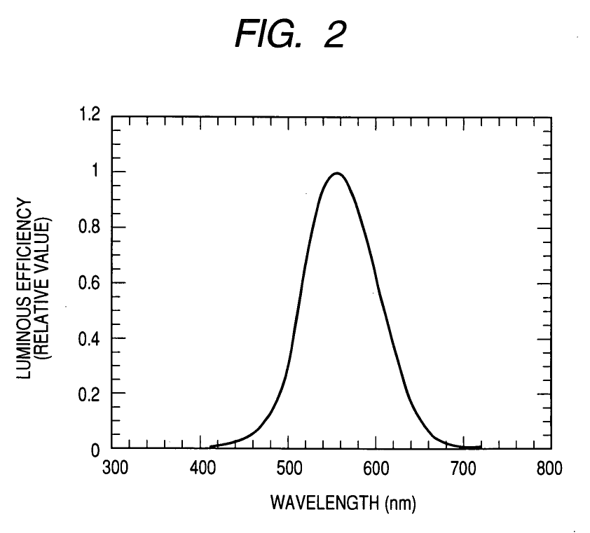

FIG. 2 is a drawing illustrating the wavelength dependence of spectral luminous efficiency. The brightness that people can feel is not proportional to the energy of incident light. As shown in FIG. 2, a peak exits in the vicinity of a wavelength of 550 nm. For instance, if light having the same energy is considered, the luminance becomes one-two hundred and fiftieth compared with the case of light of 550 nm when the light has 700 nm.

The ambient light sensing system is a function for controlling the brightness of the display corresponding to brightness that people can feel. Therefore, when an illuminance sensor following this application is considered, it is desirable that the wavelength dependence of the sensor sensitivity (hereinafter, it is called sensitivity property) matches the visual sensitivity. Herein, although visual sensitivity is being taken as an example, the sensitivity curve which is required is different and the sensor properties which are required are also different.

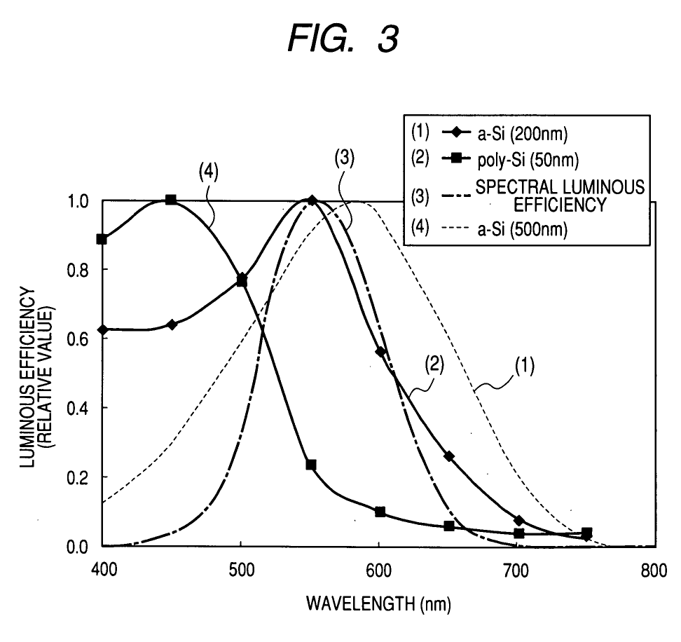

FIG. 3 is a figure for explaining the sensitivity properties of photo-sensors made of silicon materials. In the figure, (1) is the sensitivity property of a sensor fabricated by a-Si which is a PIN diode with a 500 nm thick silicon film; (2) is that of a sensor fabricated by a-Si which is a thin-film-transistor with a 200 nm thick silicon film; and (3) is that of a sensor fabricated by poly-Si which is a thin-film-transistor with a 50 nm thick silicon film. Each sensitivity property does not agree with the property of (4) spectral luminous efficiency. In order to obtain sensitivity properties which agree with the spectral luminous efficiency in one kind of sensor element, there is a means where an unnecessary wavelength band (specifically, a short wavelength side) is cut off by mounting an optical filter. However, it is not always reproducible and cost is required.

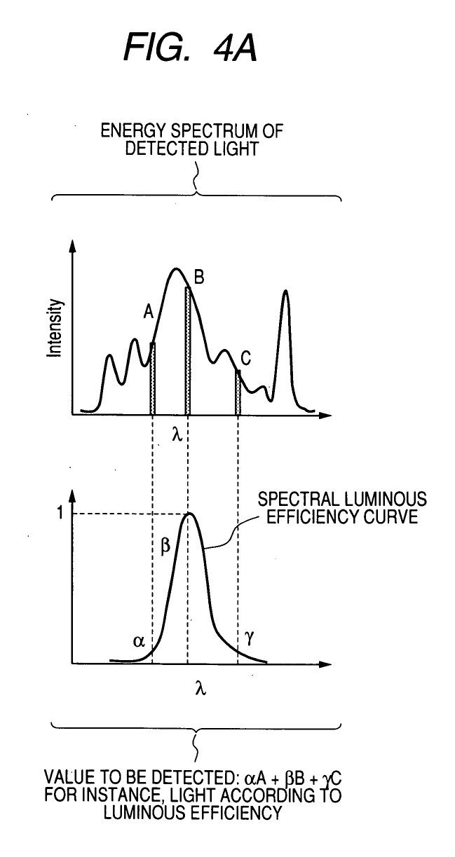

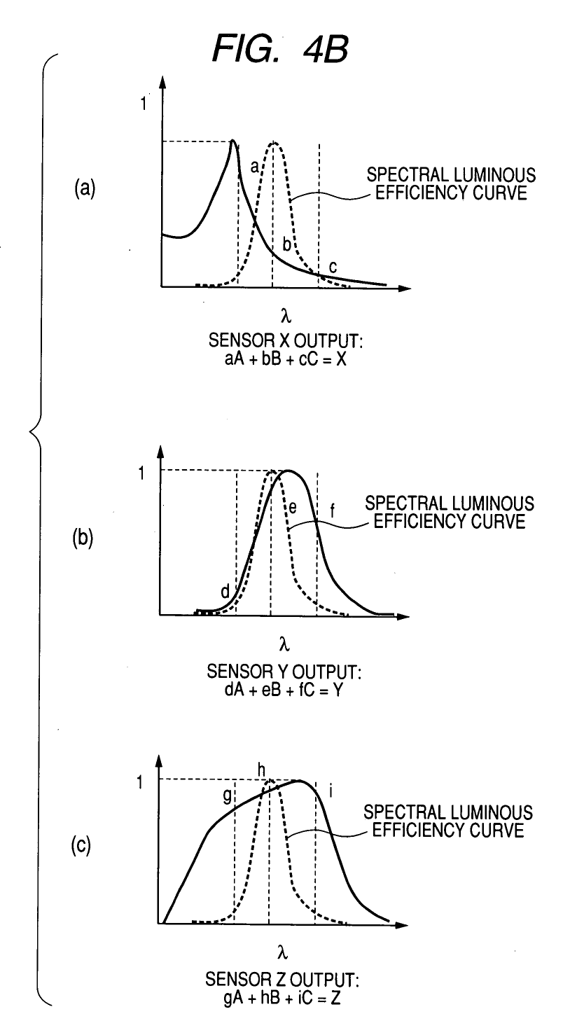

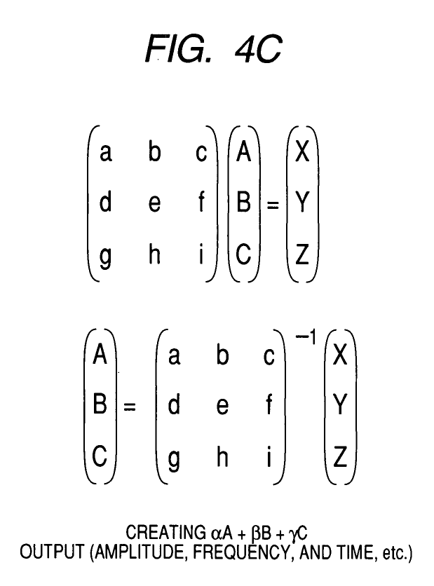

FIG. 4A are figures for showing energy spectra at the output part of the photo-sensor in the first embodiment of the present invention. FIG. 4B are figures for showing energy spectra of the output part of three different photo-sensors having different detecting regions in the first embodiment of the present invention. FIG. 4C is a figure illustrating an example of a signal calculation of the output part of the photo-sensor in the first embodiment of the present invention.

It is assumed that the detecting light has an energy spectrum as shown in FIG. 4A and three wavelength elements are shown as A, B, and C. Then, it is taken as an example where the output required to be detected is αA+βB+γC in the data according to the spectral luminous efficiency. In order to obtain this, three kinds of sensors, X, Y, and Z having different sensitivity properties are formed over the same substrate by using a pixel circuit formation process. When the sensitivity property of each sensor is shown as in FIG. 4B, respectively, the sensor output becomes X=aA+bB+cC, Y=dA+eB+fC, and Z=gA+hB+iC, respectively.

When these expressions are shown in a matrix form, it is shown as the upper formula of FIG. 4C and elements A, B, and C of the detecting light can be calculated by solving this. By multiplying an already-known factor in the calculated value, the signal αA+βB+γC is detected. When it is desired to come closer to an output which better matches the visual sensitivity, the number of wavelength elements required to be detected increases. When it is necessary to detect N kinds of wavelength elements, in principle, it will only be necessary to prepare N kinds of sensors. N will be decided by considering the required accuracy and the cost.

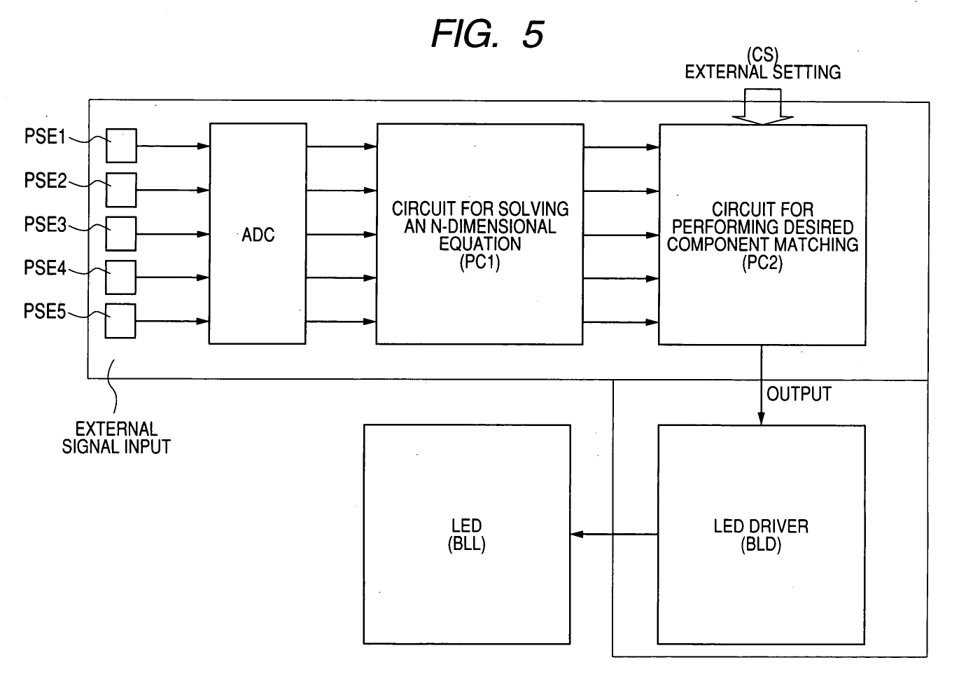

FIG. 5 is a block diagram illustrating an example of a circuit for controlling the luminance (brightness) of a light source of a backlight for a liquid crystal (herein, an LED) by processing explained in FIG. 4. In FIG. 5, although an example is shown where five outputs exist from five kinds of sensors PSE 1, PSE 2, PSE 3, PSE 4, and PSE 5 as inputs from external signals, the number is determined by considering the required accuracy and the cost as mentioned above. The sensitivity property of each sensor is examined beforehand and a well-known one is adopted. The output from the sensor is supplied as a current value and a voltage value. This is converted to a digital value by using an analog/digital converter ADC. A circuit PC 1 for solving an N-dimension equation (5 dimensions in FIG. 5) is composed, and the energy intensity of the detected light at a specific wavelength from N pieces is output.

In a circuit PC 2 where desired component matching is carried out, signals from N pieces are linearly combined and output. Factors of each element in the linear combination are determined to be values according to the spectral luminous efficiency (in the example shown in FIG. 4, they are α, β, and γ) when it is an ambient light sensing system. When it is desired to set an arbitrary factor, as shown in FIG. 5, a circuit may be formed to enable an external input setting CS. The linearly combined output signal is input to the driver BL of the light source of the backlight BLL (for instance, an LED) and controls the current value applied to the LED. Since luminance of the LED is determined by the average current value which is applied thereto, a direct current value may be controlled or the duty ratio of the current which was alternated keeping the current amplitude constant may be changed. Since the latter one has a small change of chromaticity of the backlight, it assumed that it is desirable for ambient light sensing for the liquid crystal display.

In FIG. 5, although the structure from the sensor element to the LED driver is formed over the same substrate using a pixel circuit formation process, a means may be acceptable where the structure from the circuit for solving the nth-degree equation to the LED driver BLD are formed using LSI and where a semiconductor chip is packaged. Although this involves costs for packaging, mechanical reliability can be maintained with the cost for packaging plural sensors.

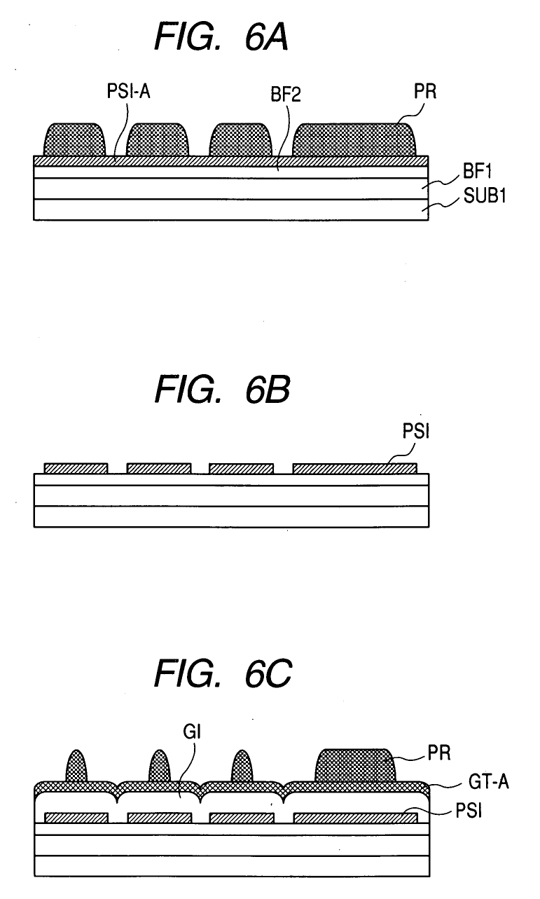

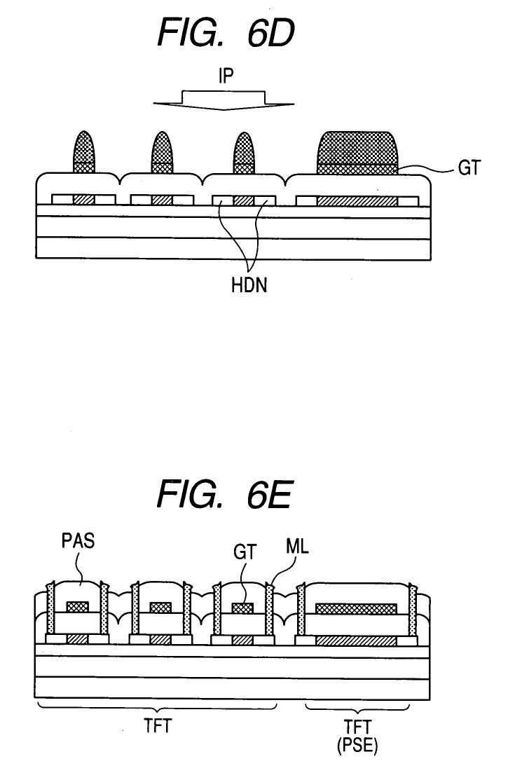

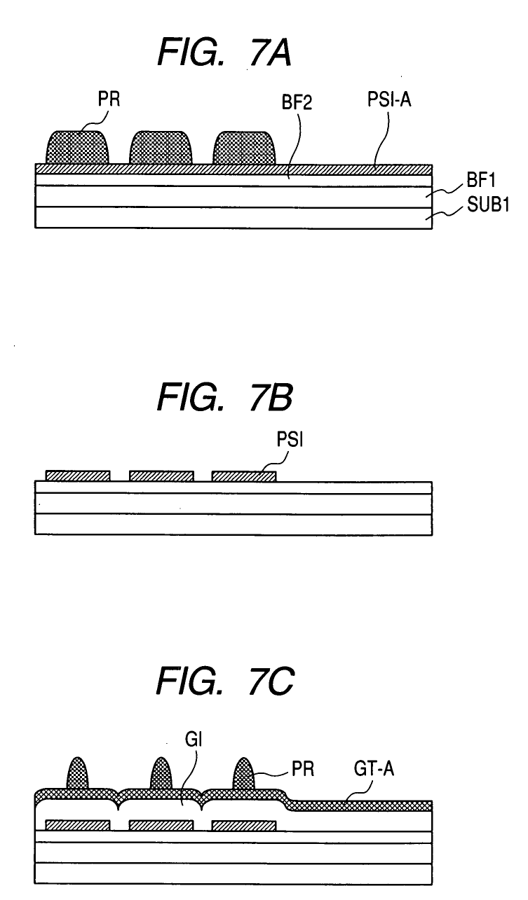

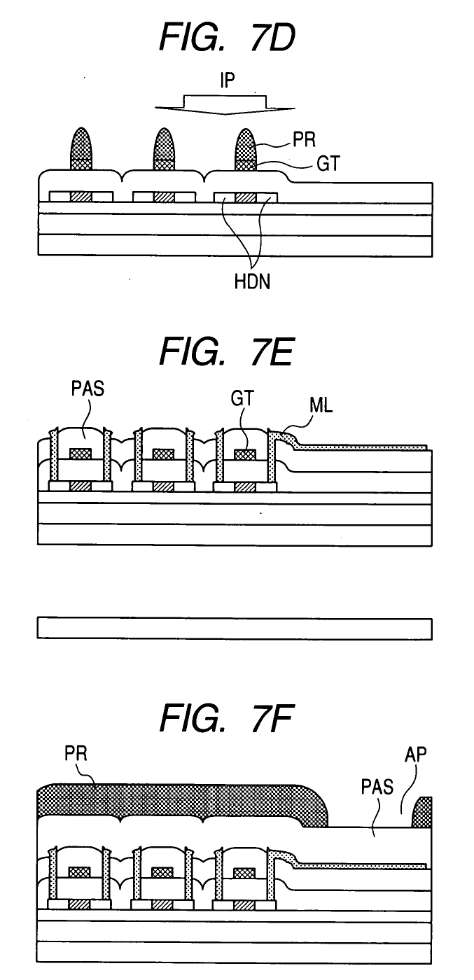

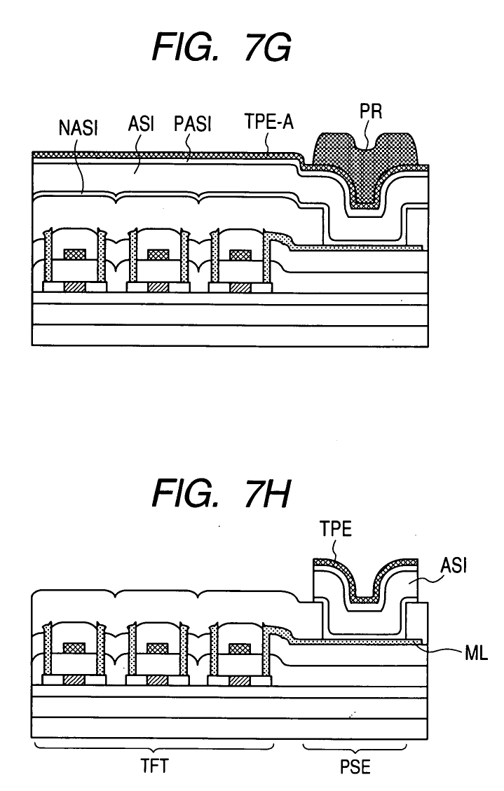

FIG. 6A to FIG. 6E and FIG. 7A to FIG. 7H are cross-sectional drawings illustrating an example process of a manufacturing method of a liquid crystal panel with an ambient light sensing system. FIG. 6A to FIG. 6E show an example of a process where a photo-sensor consists of polysilicon (poly-Si) and FIG. 7A to FIG. 7H show an example where a photo-sensor consists of amorphous silicon (a-Si).

First of all, over the first substrate SUB 1 which is an insulating substrate where a glass is suitable, a silicon nitride film (SiN) for a lower under layer BF1 and a silicon oxide film (SiO) for an upper under layer BF 2 are deposited, and a polysilicon (poly-Si) PSI-1 film is deposited thereon, in order, by using a chemical vapor deposition technique (CVD). The under layer including the first two layers, BF1 and BF2 (silicon nitride film and silicon oxide film) plays a roll for preventing contamination from the, glass substrate SUB1. Although the polysilicon film may be directly deposited by CVD, there is a means where it is formed by melt and solidification using an excimer laser, a solid-state laser, and an RTA after an amorphous silicon film including less hydrogen content or where it is formed by solid phase growth using furnace annealing, RTA, and an infrared laser. The polysilicon film is processed to be a polysilicon island PSI by a photolithographic process (FIG. 6A), (FIG. 6B).

A gate insulating film GI and a metallic film for the gate electrode GT-A are formed thereon. For the gate insulating film GI, a silicon oxide film and a silicon nitride film are preferably used. The metallic film for the gate electrode GT-A is processed by a photolithographic process and the metallic film is processed to a gate electrode GT. After that, using ion implantation IP with a photoresist PR as a mask, a source-drain region HDN is formed in the polysilicon island PSI (FIG. 6C and FIG. 6D).

In FIG. 6D, in order to introduce one kind of impurity, only one kind of polar TFT is formed (NMOS or PMOS). However, by adding a photolithographic process, it becomes possible to form a CMOS and a PIN structure with a gate. Specifically, for a thin-film-transistor TFT (PSE) in the sensor part, a PIN structure is more preferable in order to maintain sensitivity. After the implanted impurity is activated by laser annealing or furnace annealing, a passivation layer PAS is formed and an interconnect ML is formed by a photolithographic process (FIG. 6E).

FIG. 7A to FIG. 7H are cross-sectional drawings illustrating an example of a manufacturing method of a liquid crystal panel with an ambient light sensing system using a different kind of sensor (a-Si PIN) from the sensor fabricated in FIG. 6A to FIG. 6E. They show an example of a formation method. Since FIG. 7A to FIG. 7D are similar processes to those of FIG. 6A to FIG. 6D, there are no repetitive explanations.

Next, the interconnect ML is formed by a photolithographic process. At the same time, the lower electrode for a sensor connected to the interconnect ML is formed (FIG. 7E). After forming the passivation layer PAS, a hole opening is formed at the sensor part by a photolithographic process (FIG. 7F). An N-type amorphous silicon layer NASI, an intrinsic amorphous silicon layer ASI, and a P-type amorphous silicon layer PASI are continuously deposited by using a CVD technique. The film thickness is controlled by the deposition time. By combining the upper and lower electrodes, the order of the N-type and P-type can be exchanged. Then, a transparent conductive film TPE-A (herein, it is referred to as ITO) is formed at the upper part thereof (FIG. 7G).

By using a photolithographic process, the PIN sensor part is processed in an island shape to form a sensor (FIG. 7H). The counter electrode of an organic EL display (OLED) may be formed simultaneously in the formation process of the aforementioned transparent electrode TPE-A. When protection is not necessary for the exterior of the sensor part, another counter electrode may be formed independently. Furthermore, after formation of the passivation layer and formation of the transparent conductive film, a counter electrode TPE is processed by a photolithographic process.

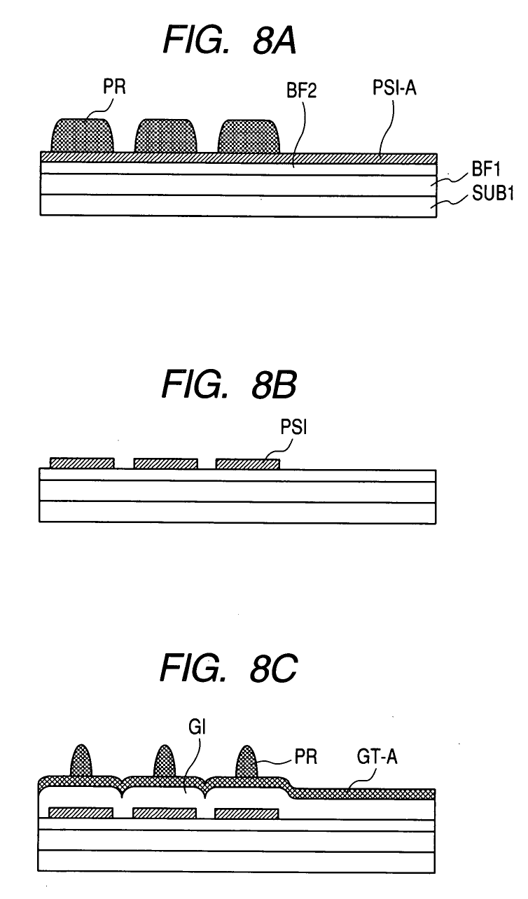

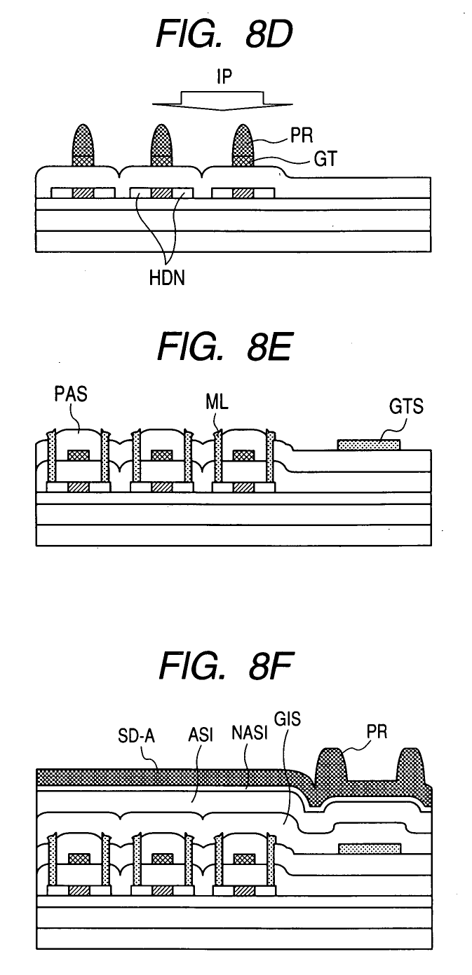

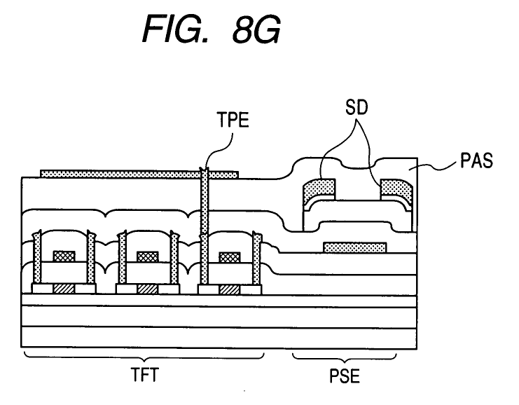

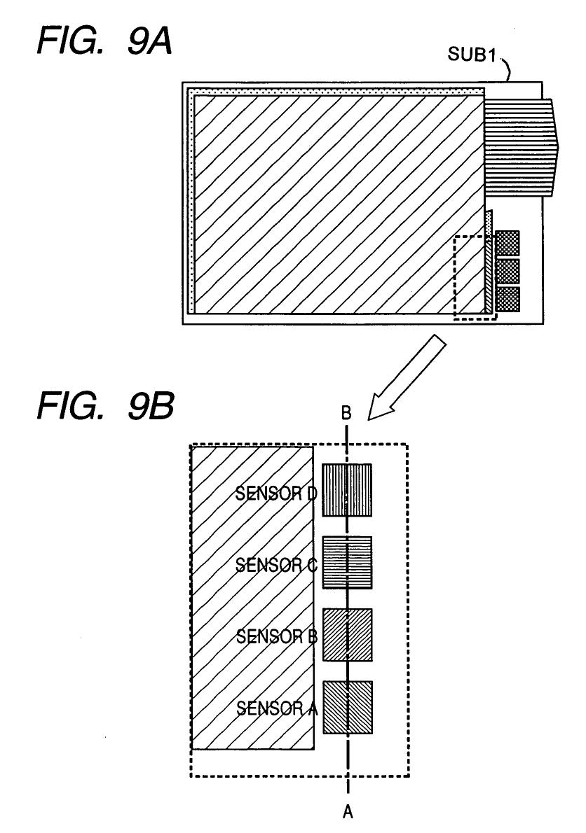

FIG. 8A to FIG. 8G show a process chart illustrating an example of a formation process of another kind of sensor which is different from a sensor of FIG. 6 and FIG. 7. Since FIG. 8A to FIG. 8A are similar processes to those of FIG. 6A to FIG. 6D, there are no repetitive explanations.

After completing the processes from FIG. 6A to FIG. 6D, the interconnect ML is formed by a photolithographic process. At the same time, the gate electrode for a sensor GTS is formed (FIG. 8E). After forming the gate insulation film GIS by using a CVD technique, an intrinsic a-Si layer ASI and an N-type a-Si layer NASI are continuously formed by using a CVD technique. Moreover, the source-drain electrode conductive film SD-A is deposited (FIG. 8F). By using a photolithographic process, the sensor part is processed in an island shape to form a sensor PSE. After the passivation film PAS is formed at the upper part, the transparent conductive film TPE is formed (ITO is used as an example in FIG. 8G) (FIG. 8G).

By performing the aforementioned processes from FIG. 6A to FIG. 6E, FIG. 7A to FIG. 7H, and FIG. 8A to FIG. 8G in parallel, another kind of a-Si sensor and a signal processing circuit explained FIG. 4A to FIG. 4C and FIG. 5 are formed.

The insulating substrate may be not limited to a glass, and may be another insulating substrate such as a silica glass or a plastic. If a silica glass is used, the process temperature can be made higher, so that reliability of the sensor and the TFT is improved and the uniformity of the sensor property is improved. Moreover, if a plastic substrate is used, a light image display apparatus with excellent shock resistance can be provided.

Although sensor elements of a variety of kinds of structures were manufactured to constitute an illuminance sensor in order to obtain a sensor output having different sensitivity properties, when the image display apparatus is a light valve projection system such as a liquid crystal panel, a sensor explained in FIG. 4A to FIG. 4C and FIG. 5 can be achieved by constructing a sensor which is formed of plural one kind of sensor if a liquid crystal layer which is the same as the pixel and a color filter are installed in the sensor part.

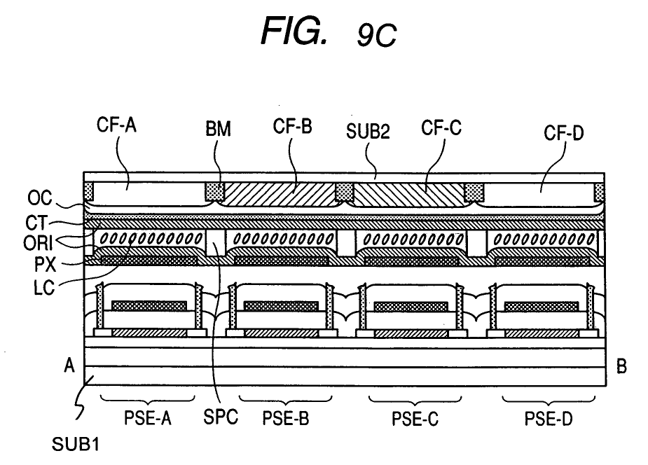

FIGS. 9A and 9B are plane views illustrating an arrangement of a photo-sensor, etc. in an illuminance detector built-in region in a panel of a liquid crystal display apparatus as an embodiment of an image display apparatus of the present invention. Sensor parts SENSOR A, SENSOR B, SENSOR C, and SENSOR D which are built into the silicon semiconductor film PSI described in FIGS. 6-8 are arranged over the main face of the first substrate SUB1. The photo-sensor consisting of this sensor part is formed in the same semiconductor film as the thin-film-transistor of the pixel which composes a pixel region at the same time in the same process.

FIG. 9C is a cross-sectional drawing taken along the line A-B of FIG. 9A. In a pixel region driven by the thin-film-transistor of the first substrate SUB1, an alignment layer ORI is formed covering the electrode PX which is the same electrode as the pixel electrode. Over the main face of the second substrate SUB2, many kinds of color filters CF-A, CF-B, CF-C, and CF-D are formed, which are partitioned by the black matrix BM. The overcoat layer OC, the counter electrode CT, and the alignment layer ORI are formed thereon.

In FIG. 9C, a photo-sensor is illustrated as an example, which includes four poly-Si TFT sensor elements (refer to FIG. 6A to FIG. 6E). These photo-sensors may include an a-Si PIN sensor (refer to FIG. 7A to FIG. 7H) and an a-Si TFT sensor (refer to FIG. 8A to FIG. 8G). The spacer SPC exists between the first substrate SUB 1 and the second substrate SUB 2, and it provides for the cell gap between both substrates.

In FIG. 9C, a detection light which comes from the upper part of the figure enters into the sensor parts PSE-A, PSE-B, PSE-C, and PSE-D through the second substrate SUB2 of the glass substrate, the color filters CF-A, CF-B, CF-C, and CF-D, and the liquid crystal layer LC. The spectrum and intensity of the detection light which enters into the sensor part are changed by passing the color filters CF-A, CF-B, CF-C, and CF-D, and the liquid crystal layer LC. The same effects as FIG. 4A to FIG. 4C can be obtained by selecting the color filter corresponding to each sensor and understanding the transmitted light properties of the color filter and the sensitivity properties of the sensor.

Moreover, when the illuminance of the ambient light is very strong and it exceeds the detection limit, the liquid crystal layer may be utilized as an aperture. The degree of the aperture can be controlled by a voltage applied to the counter electrode and, if a system capable of control (feedback) through a built-in circuit is added, a photo-sensor with a large range of illuminance detection can be achieved. Except for stray light, light from the backlight does not reach the sensor because a backlight does not exist underneath the sensor or the light is shielded.

### Second Embodiment

The second embodiment is one where an image display apparatus of the present invention is applied to an organic EL display apparatus. A panel constituting the organic EL display apparatus has the same configuration, up to the thin-film-transistor, in the first substrate of the liquid crystal panel which consists of a liquid crystal display apparatus explained in the first embodiment. In the organic EL panel, it is assumed that a pixel electrode driven by the electrode (source-drain) of the thin-film-transistor is one electrode, an organic EL light-emitting layer is coated over this one electrode, and another electrode is deposited covering plural pixels. Then, the second substrate is used as a sealing board covering another electrode. One electrode of plural photo-sensors is not coated with the organic EL light-emitting layer.

In the second embodiment, plural photo-sensors are provided over the main face of the first substrate, the same as the first embodiment, and the detecting light wavelength band is changed by using the difference of the film thickness of the semiconductor film. Or, it is assumed that the film thickness of the semiconductor film of the photo-sensor thin film transistor is the same, and the light wavelength band may be changed by installing a color filter, which is the same as one in the liquid crystal panel, at the part corresponding to the photo-sensor over the main face of the second substrate. ther configurations are similar to the first embodiment.

The present invention is not limited to a liquid crystal display apparatus and an organic EL display apparatus, and can also be applied to another image display apparatus which includes a thin-film-transistor substrate.

What is claimed is:

1. An image display apparatus comprising:
a display panel including a first insulating substrate where a pixel region is formed by arranging a plurality of pixels having a thin-film-transistor in a matrix form over the main face thereof and a second insulating substrate which is opposed and adhered to the main face of the first insulating substrate with a predetermined gap;
a driver which is provided outside of the pixel region of the first insulating substrate and which drives pixels constituting the pixel region; and
a printed circuit board where a display control circuit is mounted to supply a signal for display to the driver,
wherein the image display apparatus has a plurality of light sensors including semiconductor films constituting an active layer which is the same layer as the thin-film-transistor of the pixel circuit, in the vicinity of the pixel region at the main face of the first insulating substrate, and
wherein the plurality of light sensors have different wavelength bands of detected light.

2. The image display apparatus according to claim 1, wherein
a signal processing circuit is provided over the main face of the first substrate for generating a control signal to change the brightness of the pixel on the bases of the output of the plurality of light sensors.

3. The image display apparatus according to claim 2, wherein
the signal processing circuit is composed of a semiconductor film which is the same layer as an active layer of the thin-film-transistor with the plurality of photo-sensors.

4. The image display apparatus according to claim 3, wherein
a feedback circuit is included where the display control circuit applies a control signal to the driver for changing the brightness of the pixel on the basis of a control signal generated by the signal processing circuit.

5. The image display apparatus according to claim 4, wherein
the feedback circuit is mounted over the printed circuit board.

6. The image display apparatus according to claim 1,
wherein a liquid crystal is enclosed in the gap between the first insulating substrate and the second insulating substrate, and
wherein a backlight installed on the backside of the first insulating substrate and a source circuit which controls lighting the backlight are included.

7. The image display apparatus according to claim 6, wherein
each of the plurality of photo-sensors detects light with a different wavelength band by changing the film thickness of the semiconductor film.

8. The image display apparatus according to claim 6, wherein
a color filter having different transmission wavelength bands which is arranged to be opposite each of the plurality of photo-sensors over the main face of the second substrate.

9. The image display apparatus according to claim 1, wherein
a plurality of organic EL light-emitting layers having different luminescent colors over one electrode driven by a plurality of thin film transistors which constitute the pixels contained over the main face of the first insulating substrate and another electrode covering the plurality of organic EL luminescent layers are provided.

10. The image display apparatus according to claim 9, wherein
each of the plurality of photo-sensors detects light with a different wavelength band by changing the film thickness of the semiconductor film.

11. The image display apparatus according to claim 9, wherein
a color filter having different transmission wavelength bands is provided on the upper side of each of the plurality of photo-sensors.
